(19) United States
(12) Patent Application Publication
(10) Pub. No.: US 2004/0129561 A1
(43) Pub. Date: Jul. 8, 2004

(54) Cylindrical magnetron magnetic array mid span support

(75) Inventors: Richard Lowe Barrett, Goffstown, NH (US); Philip A. Greene, Oakland, CA (US)

Correspondence Address: Skjerven morrill LLP, 28th Floor, 3 Embarcadero Center, San Francisco, CA, 94111, US

(73) Assignee: Von Ardenne Anlagentechnik GmbH

(21) Appl. No.: 10/338,190

(22) Filed: Jan. 7, 2003

(51) Int. Cl. C23C 14/32

(52) U.S. Cl. 204/298.21; 204/298.22; 204/192.1

(57) ABSTRACT

A support assembly for the magnetic array in a cylindrical magnetron that greatly reduces the stress placed on the assembly and on the end blocks of the magnetron. The support assembly and method also reduce the time necessary for properly positioning the magnetic array in relation to the target tube, and result in uniform positioning of the magnetic array along the length of the target tube. A cylindrical magnetron incorporating such an assembly produces uniform coatings and requires less adjustment and maintenance.

### BACKGROUND

1. Field of the Invention

The present invention generally relates to sputtering systems, and more particularly to positioning of a magnetic array within a cylindrical magnetron.

2. Related Art

A cylindrical magnetron utilizes a magnetic array within a target tube. Proper sputtering is dependent upon proper alignment and positioning of the magnetic array within the target tube. Not only must the magnetic array must be properly aligned when installed, in order to ensure proper sputter, the alignment should be maintained until it is necessary to install a new target tube. Prior designs, required a labor intensive, time consuming process that only very skilled technicians could quickly carry out. Furthermore, the magnetic array would frequently become misaligned after only a short time of usage because highly stressed portions of the assembly lead to rapid degradation of the rollers and other various parts.

Several U.S. patent applications describe cylindrical magnetrons and the various configurations of magnetic arrays, target tubes, and other components, all of which are hereby incorporated by reference in their entireties: U.S. Pat. No. 5,108,574 to Kirs et al; U.S. Pat. No. 5,213,672 to Hartig, et al; U.S. Pat. No. 5,364,518 to No. Hartig, et al; U.S. Pat. No. 5,527,439 to Sieck, et al; U.S. Pat. No. 5,725,746 to Dickey et al; and U.S. Pat. No. 5,853,816 to Vanderstraeten.

FIGS. 1A-1C illustrate an example of a prior magnetic assembly 102. Assembly 102 is stationary within a rotating target tube 104 of a cylindrical magnetron. The assembly includes a magnetic array 106 that is mounted to a support pipe 112 that runs the length of the target tube 104. The magnetic array 106 has a backing plate 108 between the support pipe 112 and the array 106. For practical purposes the backing plate 108 will be considered part of magnetic array 106. The support pipe 112 is coupled to the magnetic array 106 via clamps 116 positioned at various points along the pipe and array. The rollers 124 are in tangential contact with the inner diameter of the target tube 104. The rollers are also fixed directly to the magnetic array 106, as seen in FIG. 1B. Thus, the magnetic array 106 is not adjustable in relation to the inner diameter of target tube 104, and has very little freedom of movement. However, fine tuning is possible by deflecting the assembly 102 in along the length of the assembly.

The position of the magnetic array is fine tuned by manipulating shims 120 located between the clamps 116 and the magnetic array 106. Different amounts of shimming may be placed at the different clamps 116. The magnetic array is not free to move, and as a result is not displaced by the full thickness of the shim. This may result in a different amounts of deflection, at times approaching a quasi sinusoidal like pattern. The shimming increases the loading on the rollers and on the end circumference support areas of the support tube. This results in increased compression stresses and premature wear of the rollers and the circumferential end supports. The wear of the rollers, in turn, leads to movement and misalignment of the magnetic array. This misalignment results in less than optimal sputtering with variations in the coatings produced by the magnetrons. Therefore, a more durable and simpler device and method for positioning the magnetic array is needed.

### SUMMARY

A magnetic support assembly is located within the target tube of a cylindrical magnetron, and supports a magnetic array within the target tube. The position of the magnetic array is critical to the sputtering of the target tube material. The support assembly uniformly supports the magnetic array such that the distance between the magnetic array and the target tube is constant along the length of the magnetic array. This results in even and uniform sputtering, and therefore even and uniform coatings on the substrate.

The magnetic support assembly comprises a support member. Rollers attached to the support member are in contact with an inner diameter of the target tube and support the stationary support member as the target tube continually rotates. An support structure is attached to a magnetic array, and the support structure and magnetic array are positioned between the rollers of the support member. The support structure has a length approximately equal to that of the target tube, and the magnetic support assembly is positioned at approximately the middle of the target tube and supports the weight of the magnetic array and support structure from the approximate middle of the target tube.

Another aspect of the invention is a method for positioning a magnetic array having a span within the target tube of a cylindrical magnetron. The method comprises affixing the magnetic array to a supporting member along the span of the magnetic array, attaching a roller structure to the supporting member at about the middle of the span adjusting a distance between the roller structure and the support member in order to position the magnetic array relative to an inner surface of the target tube. The roller structure, support member, and magnetic array are inserted into the target tube such that the roller structure is at about the middle of the target tube.

### BRIEF DESCRIPTION OF THE FIGURES

FIG. 1A is a perspective view of a prior art magnetic assembly 102.

FIG. 1B is a perspective view of a prior art magnetic assembly 102 seen in FIG. 1A.

FIG. 1C is a cross section of a prior art magnetic assembly 102.

FIG. 2A is a cross section of magnetic support assembly 202.

FIG. 2B is a cross section of magnetic support assembly 250.

FIG. 2C is a cross section of magnetic support assembly 250.

FIG. 2D is a cross section of magnetic support assembly 275.

FIG. 3A is a perspective view of magnetic support assembly 300 partially in a target tube.

FIG. 3B is a perspective view of a support pipe and the fixation with the end block.

FIG. 4 is a perspective view of magnetic support assembly 400.

FIG. 5 is a graph of a deposition profile created by an embodiment of the invention.

Like numbers are used to describe the same components in the various figures.

### DETAILED DESCRIPTION

All of the embodiments of the present invention simplify the installation of a magnetic support assembly within the target tube of a cylindrical magnetron. Additionally, the embodiments result in more uniform coatings, both initially, and after many hours of operation. The embodiments improve the load and stress distribution within the target tube and upon the end blocks of the magnetron, minimize friction between the rotating parts, and provide for true adjustability of the distance between the magnetic array and the target tube. The magnetic array, once installed will remain precisely aligned during the period of time that elapses while the target erodes for the life of the target tube. This results in a magnetron that produces uniform coatings for extended durations without the need for re-adjustment due to wear or other stress induced variations in the component parts. Should any adjustment be necessary, it can be performed at a convenient time, such as when the target tube is changed.

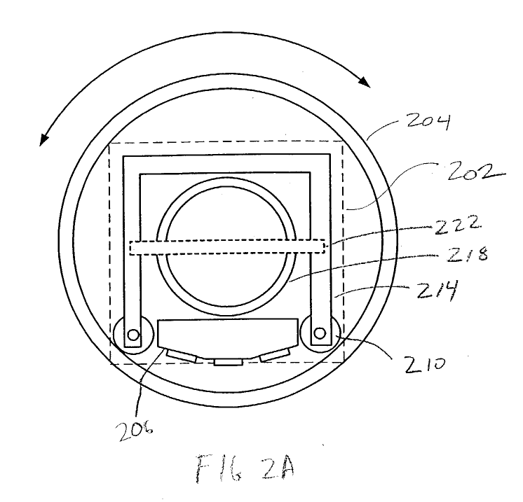

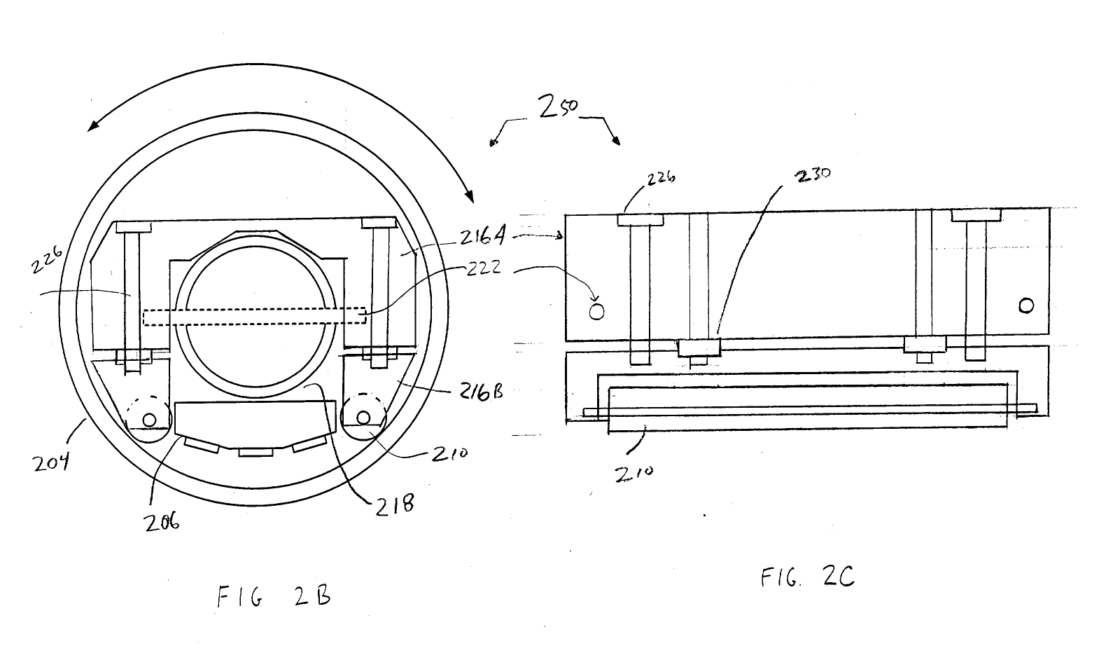

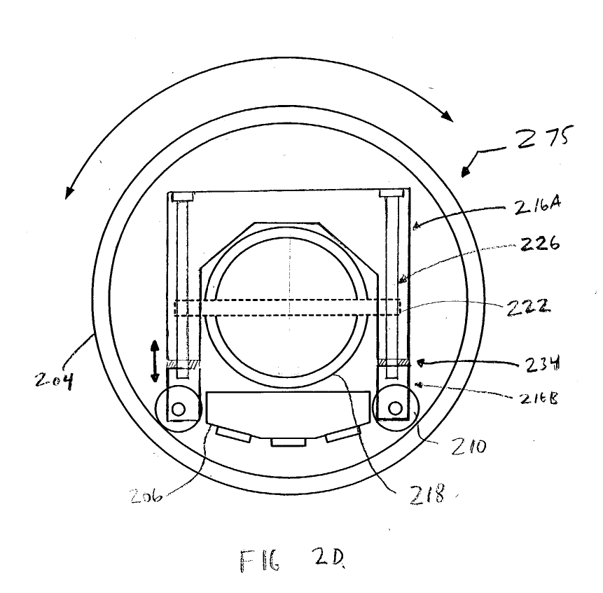

FIG. 2A. is a cross section illustrating magnetic support assembly 202, an embodiment of the present invention, within target tube 204. Magnetic support assembly 202, and all the magnetic support assemblies that will be described, are stationary within the rotating target tube 204.

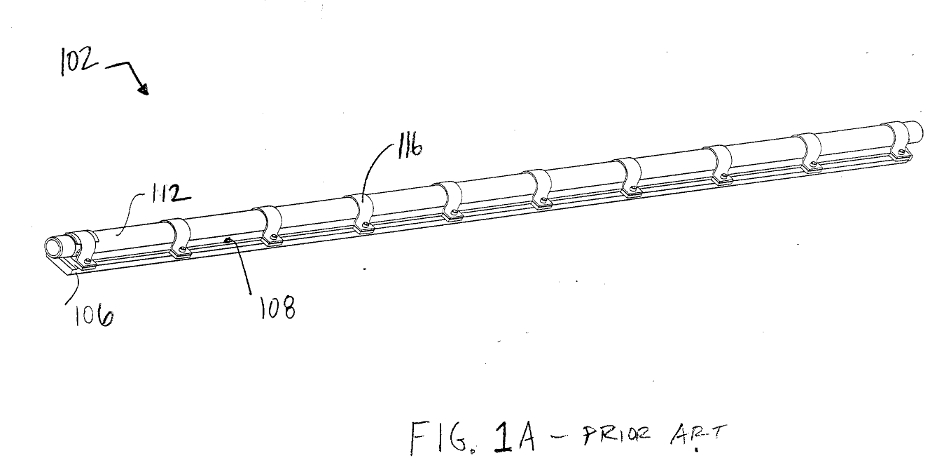

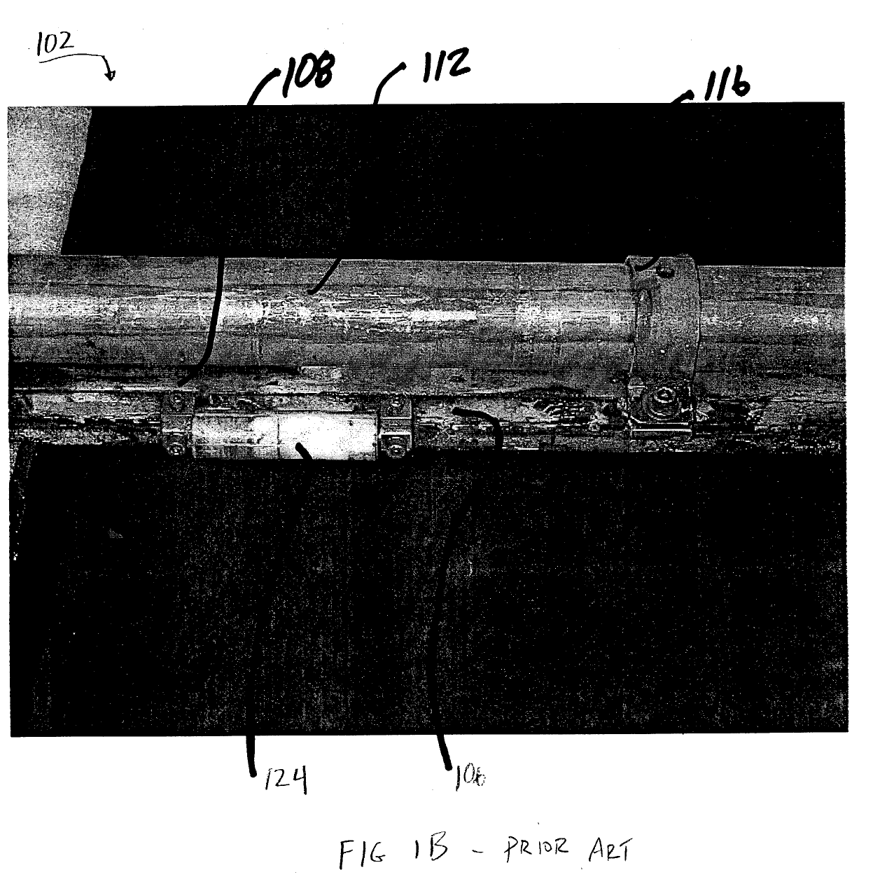

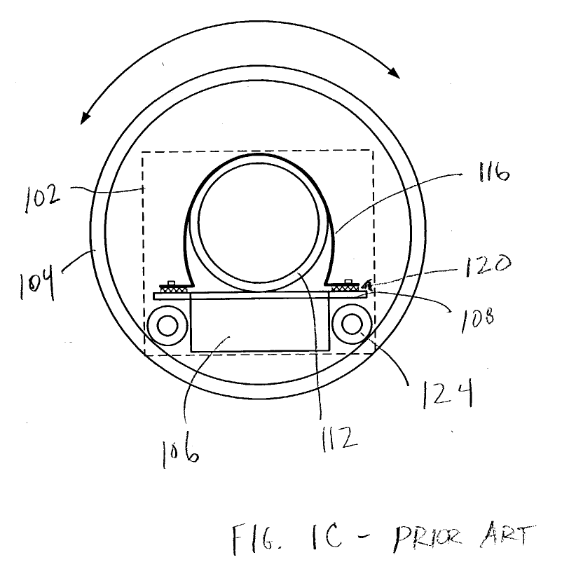

Magnetic support assembly 202 is a fixed design, i.e. the distance between the magnetic array and target tube 204 is not adjustable at the support assembly. Support pipe 212 is secured to the u-shaped support frame 214 by cross pins 222. Magnetic array 206 is secured to support pipe 218 in any number of ways. It may be secured with screws or bolts that attach directly to support pipe 218, or may alternatively be secured to a backing plate, which is intern secured to support pipe 218. It may also be, for example clamped to the support pipe at various points along the pipe, in a manner similar to that shown in FIG. 1A, or otherwise adhered in any well-known way.

Although support frame 214 is depicted as a simple u-shape, any number of different geometries are within the scope of the present invention. For example, frame 214 may include a hemispherical or stepped inner portion that more closely follows the shape of the cylindrical support pipe 218. Furthermore, the support pipe 218 may be of any geometry. Preferably, support pipe 218 acts a conduit for cooling water provided by one of the magnetron end blocks (not shown). However, support pipe 212 may also be a solid member. The magnetron and the end blocks are described in co-pending application Ser. No. 10/052732 to Richard Barrett, filed on Jan. 18, 2002, and entitled Cylindrical AC/DC Magnetron With Compliant Drive System And Improved Electrical And Thermal Isolation, which is hereby incorporated by this reference in its entirety.

FIGS. 2B and 2C illustrate magnetic support assembly 250, another embodiment of the present invention. Assembly 250 allows adjustment of the distance between the magnetic array 206 and target tube 204. There are two portions of the frame, upper frame 216A, and lower frame 216B. The support pipe 218 is connected to upper frame 216A with connecting pins 222. The support pipe may be connected to the upper frame 216A in any number of ways such as with rivets, screws, adhesive material, clamps, or by welding. Furthermore, the support pipe 218 may be integrally formed with the upper frame 216A, and/or lower frame 216B, in which case the support pipe and (a portion of) the frame would be considered one piece.

The lower frame 216B has the rollers 210 that contact the inner diameter of the rotating target tube 204. The lower frame may be as large or small as desired, and in fact, if the lower frame is minimized it may comprise only rollers and an adjustable coupling to the rollers that adjusts to vary the distance between the rollers (in contact with the inner diameter of the target tube) and the magnetic array 206. Set screws 230 in lower frame 216B are used to adjust the distance between magnetic array 206 and target tube 204 by varying the distance between upper frame 216A and lower frame 216B. The set screws are accessed through passages in upper frame 216A. Clamp screws 226 hold the upper and lower frame together. The set screws 230 are shown threaded into lower frame 216B, however the set screws may be configured many different ways, such as for example being threaded in the upper frame 216A and abutting a solid portion of lower frame 216B or vice versa.

FIG. 2D illustrates magnetic support assembly 275, another embodiment of the present invention. Magnetic support assembly 275 is similar to magnetic support assembly 250, but shims 234 are used to vary the distance between the magnetic array 206 and the target tube 204. The shims 234 are positioned between upper frame 216A and lower frame 216B in order to vary the distance between the upper and lower frame and thus between the magnetic array 206 and the inner diameter of target tube 204.

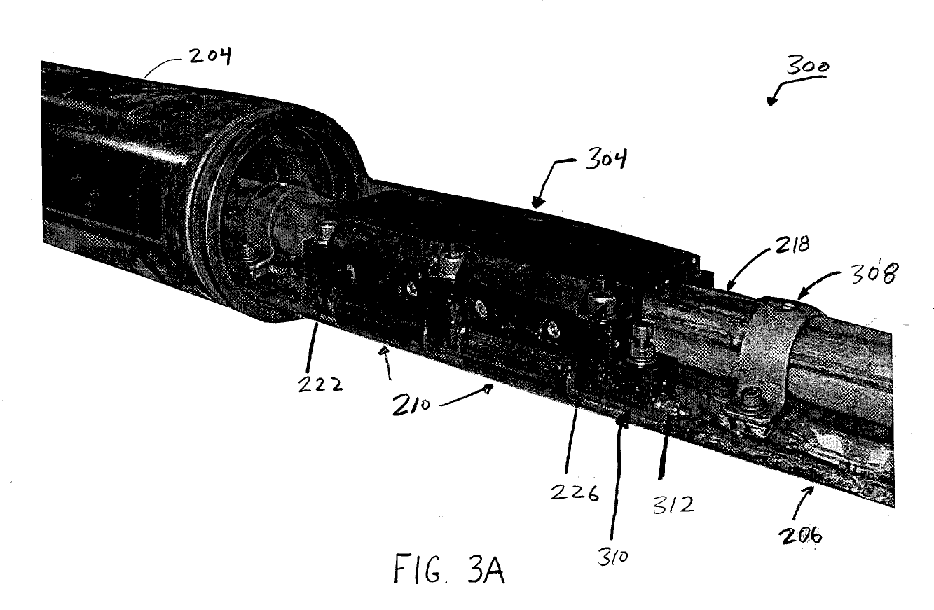

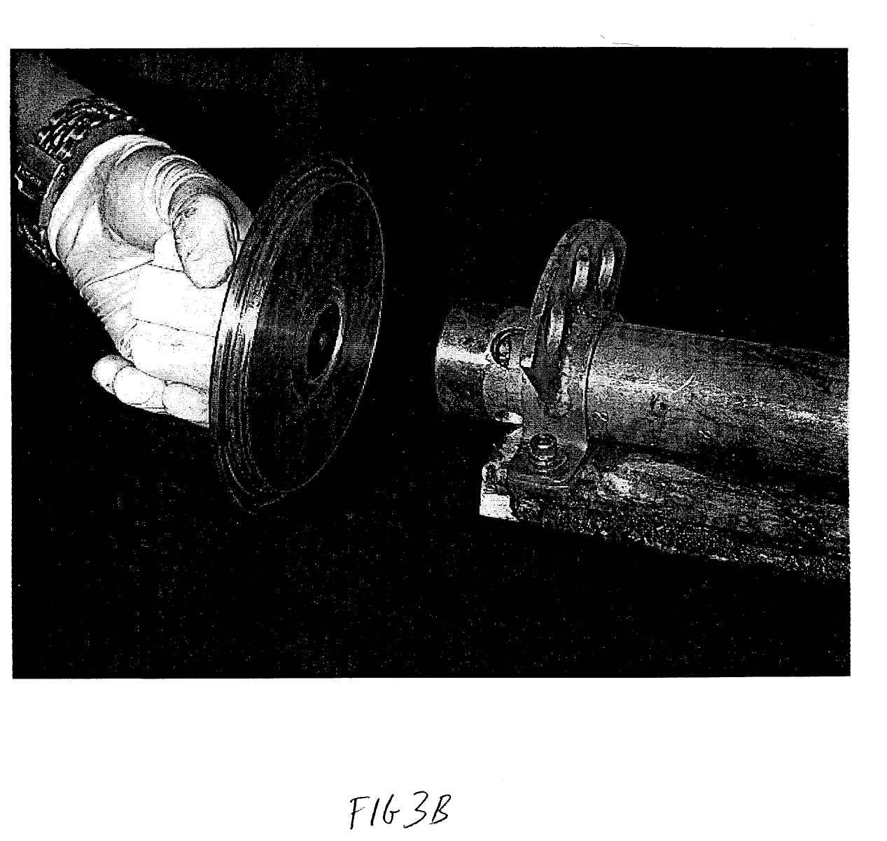

FIG. 3A illustrates magnetic support assembly 300 according to another embodiment of the invention. Assembly 300 has a fixed frame 304 with two rollers 210 per side. The previously described assemblies had one roller per side. It is envisioned that any number of rollers can be included in an assembly, although preferably two are included to minimize cost. The rollers are made of a very durable material such as nylon that does not break down in water, or in very high electrical and magnetic fields, and the very high temperatures common in high power cylindrical magnetrons. Preferably the nylon has other constituents such as finely divided particles of molybdenum disulphide (MoS²) to enhance its load bearing capabilities while maintaining the impact resistance inherent to nylon. Additionally, it is preferred that the nylon (composite) is cast, although it may also be extruded or otherwise formed, and includes oil or other lubricant for improved frictional characteristics. Furthermore, the rollers 210 are continually lubricated from lubricant reservoir 310. The reservoir is filled with lubricant through nipple 312 prior to installation of the magnetic support assembly 300 into target tube 204. Although the reservoir can easily be periodically refilled, it is sufficiently large to provide continual lubrication throughout the life of a target tube. Clamp 308 holds the magnetic array 206 to the support pipe 318, one of the many ways discussed earlier of adhering support pipe 318 to magnetic array 206.

In all of the embodiments discussed thus far, the magnetic array 206 and support pipe 218 are supported in three positions. At each end of the target tube 204 there is an end plate 320, as can be seen in FIG. 3B. Each end plate 320 has a circular groove in which support pipe 218 fits. The end plate and the groove support the pipe 218 at each end of the pipe. The support pipe is approximately the length of the target tube, but may be slightly longer or shorter than the target tube, depending on the particular configuration of the end block utilized. The magnetic support assemblies depicted in all of the various figures are positioned at roughly the middle of the length of the support pies 218 so that when they are inserted into a target tube 204, they will support and position the magnetic array 206 at roughly the middle of the target tube. While it is preferred to use one support assembly in the middle of the pipe and target tube, more than one support assembly can be utilized to support the pipe and magnetic array at various locations along the pipe. While this is more costly, in coating situations requiring long target tubes where sagging of the support pipe is more likely, or in situations where very high precision is of the utmost importance, utilizing more than one support assembly may be advantageous.

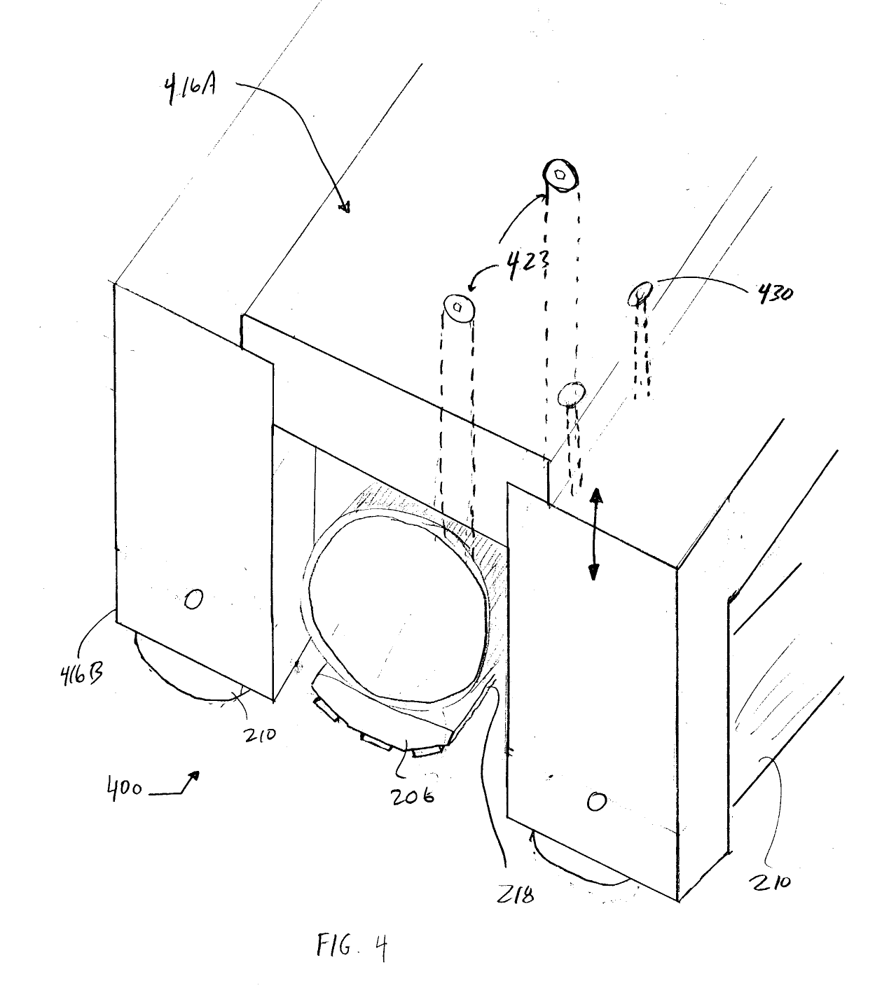

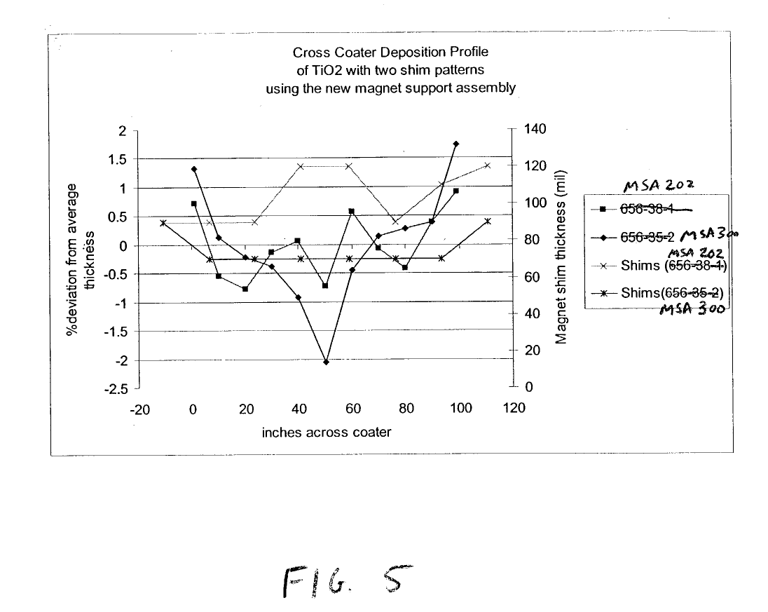

FIG. 4 is a perspective view of magnetic support assembly 400. Magnetic support assembly 400 comprises an upper frame 416A and a lower frame 416B. The support pipe and magnetic array 206 are connected to upper frame 416A with support pins 423. Upper frame 416A can be separated from lower frame 416b by jack screws 430. This intern varies the distance between the magnetic array 206 and the inner diameter of the target tube (not shown). Support pins 423 may also be used to vary the distance between the magnetic array and the target tube.

FIG. 5 is a graph of a TiO₂ coating deposited with a cylindrical magnetron utilizing an embodiment of the present invention, and with a cylindrical magnetron using a prior art magnetic support assembly (shortly after installation and alignment) as seen in FIG. 1. The coating deposited with present invention is much more uniform across the entire length of the coater. The uniformity profiles shown are after the prior support assemblies were freshly tuned, under optimum conditions. As described previously, the prior assembly was prone to quickly lose alignment and thus would typically result in a coating inferior to the one shown in the graph, whereas the present invention solves that problem, and produces uniform coatings for the life of the target tube. Therefore, a coater utilizing any of the embodiments of the present invention will produce a coating far superior to that produced with prior designs.

While particular embodiments of the present invention and their advantages have been shown and described, it should be understood that various changes, substitutions, and alterations can be made therein without departing from the spirit and scope of the invention as defined by the appended claims.

1. A method for positioning a magnetic array having a span within the target tube of a cylindrical magnetron, the method comprising:
affixing the magnetic array to a supporting member along the span of the magnetic array;
attaching a roller structure to the supporting member at about the middle of the span;
adjusting a distance between the roller structure and the support member in order to position the magnetic array relative to an inner surface of the target tube; and
inserting the roller structure, support member, and magnetic array into the target tube such that the roller structure is at about the middle of the target tube.

2. The method of claim 1 wherein adjusting the distance comprises turning a set screw.

3. The method of claim 1 wherein adjusting the distance comprises inserting one or more pieces of material between the roller structure and the support member.

4. A magnetic support assembly in a cylindrical magnetron having a target tube, the magnetic support assembly comprising:
a U-shaped member;
rollers attached to the U-shaped member, the rollers in contact with an inner diameter of the target tube; and
an elongated support structure attached to a magnetic array, the support structure and magnetic array positioned between the rollers of the U-shaped member,
the elongated support structure having a length approximately equal to that of the target tube, the magnetic support assembly positioned at approximately the middle of the target tube and supporting the weight of the magnetic array and support structure from the approximate middle of the target tube.

5. The magnetic support assembly of claim 4 further comprising an adjustment mechanism that changes the distance of the magnetic array in relation to an inner surface of the target tube.

6. The support assembly of claim 4 further comprising a lubrication reservoir that provides continual lubrication to the rollers during operation of the magnetron.

7. The support assembly of claim 4 wherein the rollers comprise nylon.

8. The support assembly of claim 7 wherein the rollers further comprise molybdenum disulphide and a lubricant.

9. A method for positioning a magnetic array having a span within the target tube of a cylindrical magnetron, the method comprising:
affixing the magnetic array to a support member along the span of the array;
supporting the magnetic array and supporting member at the middle of the magnetic support member with a cradle that contacts the inner circumference of the target tube with rollers (wheels) and can be used to adjust the distance of the magnet from the inner circumference of the target tube; and
inserting the roller structure, support member, and magnetic array into the target tube such that the roller structure is at about the middle of the target tube.

10. A method of supporting and positioning a magnetic array within a cylindrical target tube of a magnetron, the target tube having a length and an inner circumference, the magnetic array spanning the target tube, the method comprising:
attaching a support member spanning the length of the target tube to the magnetic array;
supporting the support member at three positions, at least one of the positions at the mid-span of the support member.

11. The method of claim 10 further comprising:
adjusting the distance of the magnet from the inner circumference at the mid-span of the support member.

12. The method of claim 11 wherein adjusting the distance comprises varying the distance between an upper and a lower portion of a support frame, one of the portions operable to move freely relative to the other portion.

13. The method of claim 12 wherein adjusting the distance comprises adjusting one or more screws including at least one set-screw.

14. The method of claim 12 wherein adjusting the distance comprises inserting shims between the upper and lower portions of the support frame.

15. The method of claim 10 wherein supporting comprises bearing a load and distributing the load, the load at the middle of the span supported by the target tube through one or more rotating elements.

16. A cylindrical magnetron comprising:
a target tube having sputtering material;
a magnet within the target tube;
a support member within the target tube, the support member coupled to the magnet and having a principle axis parallel to principle axes of the target tube and magnet; and
a centrally located support structure coupled to the support member,
the support structure having an adjustment mechanism that changes the position of the magnet relative to the sputtering material of target tube,
the position of the magnet adjusted with the adjustment mechanism relative to the target tube prior to insertion of the magnet and support structure into the target tube.

17. The magnetron of claim 16 wherein the support structure adjustment mechanism comprises one or more set screws that adjust the position of the support member and magnet relative to an inner surface of the target tube.

18. The magnetron of claim 16 wherein the support structure adjustment mechanism comprises shims that adjust the position of the support member and magnet relative to an inner surface of the target tube.

19. The magnetron of claim 16 wherein the magnet is affixed to the support member, and wherein the support member is moveable relative to the support structure.

20. In a cylindrical magnetron comprising a target tube and a magnetic array, a magnetic array support structure comprising:
means for supporting and positioning a magnetic array at the center of gravity of the magnetic array, so as to eliminate sagging of the array at the center of gravity.
